(19) United States
(12) Patent Application Publication
(10) Pub. No.: US 2026/0057871 A1
(43) Pub. Date: Feb. 26, 2026

(54) PASSIVE ACOUSTIC NOISE SUPPRESSING RESONATORS USING QUARTER-WAVELENGTH CAVITIES

(71) Applicant: Dell Products L.P., Round Rock, TX (US)

(72) Inventors: Tejinder Singh, Manotick (CA); Navjot Kaur Khaira, Manotick (CA)

(21) Appl. No.: 18/813,987

(22) Filed: Aug. 23, 2024

(51) Int. Cl. G10K 11/172; G10K 11/162; H05K 7/20

(52) U.S. Cl. CPC G10K 11/172; G10K 11/162; H05K 7/20718

(57) ABSTRACT

The technology described herein is directed towards metasurfaces that include one or more quarter-wavelength resonators for sound absorption, in which the metasurface and the one or more resonators are deployed proximate to a server. Each quarter-wavelength resonator is designed and constructed based on a specific resonance frequency, and for compactness includes meandering air trace lines dimensioned to resonate at the desired resonance frequencies and thereby cancel corresponding narrowband frequencies of incoming sound waves. The metasurfaces can be arranged in a modular structure, and can suppress noise peaks of multiple (e.g., five) fundamental frequencies and their harmonics. The metasurfaces can be printed, and the quarter-wavelength resonators can be coupled to heat dissipating material and/or a heatsink; a fan can help dissipate the heat from the quarter-wavelength resonators.

### RELATED APPLICATION

The subject patent application is related to U.S. patent application Ser. No. ______, filed ______, and entitled “MULTIBAND ACOUSTIC NOISE SUPPRESSING METASURFACE USING THERMALLY CONDUCTIVE QUARTER-WAVELENGTH CAVITIES” (docket no. 139385.01/DELLP1276US), the entirety of which patent application is hereby incorporated by reference herein.

### BACKGROUND

Acoustic absorbers are specialized materials or structures designed to mitigate the effects of sound reflections, echoes, and reverberations in various environments. These absorbers function by capturing sound waves and converting their energy into heat, effectively reducing the intensity of the sound waves and preventing them from bouncing off surfaces and causing unwanted sound reflections. They are typically engineered using porous materials with intricate structures that allow sound waves to penetrate deep into the material, where the acoustic energy is dissipated as thermal energy through friction and air resistance.

Existing acoustic absorbers come in various forms, including foam panels, fabric-wrapped panels, diffusers, bass traps, and more. One of the problems with existing acoustic absorbers is that they are not desirable in certain heat-sensitive environments. For example, servers generate a lot of heat and thus are designed with fans to cool dissipate the heat; however, fans can generate a lot of annoying noise. Using existing acoustic absorbers to absorb server noise reduces the noise, but can significantly reduce dissipation of the heat generated by servers, which can result in high heat levels that can reduce server performance and possibly cause a server to shut down to avoid damage from overheating.

### BRIEF DESCRIPTION OF THE DRAWINGS

The technology described herein is illustrated by way of example and not limited in the accompanying figures in which like reference numerals indicate similar elements and in which:

FIG. 1 is top view representation of an example acoustic metasurface of five passive acoustic noise suppressing resonators for five frequencies using quarter-wavelength cavities (air traces), in accordance with various example embodiments and implementations of the subject disclosure.

FIG. 2 is a three-dimensional (3D) perspective view representation of an example metasurface with five passive acoustic noise suppressing resonators for five frequencies using quarter-wavelength cavities, in accordance with various example embodiments and implementations of the subject disclosure.

FIG. 3 is a top view representation of an example enlarged portion of a metasurface showing one of the acoustic noise suppressing resonators and acoustic pressure therein, in accordance with various example embodiments and implementations of the subject disclosure.

FIG. 4 is a is a top view representation of an example frequency map for a metasurface with five air traces corresponding to five passive acoustic noise suppressing resonators for five frequencies, in accordance with various example embodiments and implementations of the subject disclosure.

FIG. 5 is a graphical representation showing different lengths of air traces corresponding to quarter wavelengths for different frequencies, in accordance with various example embodiments and implementations of the subject disclosure.

FIG. 6 is a graphical representation showing different peak frequencies and harmonics to absorb via the quarter resonators, in accordance with various example embodiments and implementations of the subject disclosure.

FIG. 7 is a is a top view representation of example plating with high thermal conductivity used to dissipate heat in a quarter wavelength transmission line, in accordance with various example embodiments and implementations of the subject disclosure.

FIG. 8 is a 3D perspective view representation of a foldable design for quarter-wavelength resonator(s), in accordance with various example embodiments and implementations of the subject disclosure.

FIG. 9 is a block diagram showing an example system for implementing a metasurface with quarter-wavelength resonators for noise cancellation by phase canceling five frequencies in acoustic waves, in which heat dissipating material and a fan can be used for heat dissipation of the resonators in accordance with various embodiments and implementations of the subject disclosure.

FIG. 10 is a flow diagram showing example operations related outputting design parameters of an acoustic metasurface module having an intake port, and respective meandering air trace lines having respective lengths corresponding to the respective quarter-wavelength distances of frequencies to cancel, in accordance with various embodiments and implementations of the subject disclosure.

### DETAILED DESCRIPTION

Various embodiments and implementations of the technology described herein are generally directed towards a sound absorbing device based on quarter-wavelength resonators deployed proximate to a server. In one implementation, the metasurface is configured to be attached to or otherwise closely coupled to a server housing.

The technology described herein facilitates the design and implementation of such quarter-wavelength resonators that can be configured and positioned to efficiently absorb and dissipate sound waves of one or more specific frequencies. Significantly, the use of quarter-wavelength resonator-based metasurfaces as described herein does not increase the heat levels of computing devices substantially compared to existing technologies for sound absorption that do not facilitate ventilation/do not dissipate the heat very well. At the same time, such quarter-wavelength resonator-based metasurfaces are relatively thin compared to other noise suppressing metasurfaces.

Reference throughout this specification to “one embodiment,” “an embodiment,” “one implementation,” “an implementation,” etc. means that a particular feature, structure, or characteristic described in connection with the embodiment/implementation is included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, or characteristics may be combined in any suitable manner in one or more embodiments/implementations. It also should be noted that terms used herein, such as “optimize,” “optimization,” “optimal,” “optimally” and the like only represent objectives to move towards a more optimal state, rather than necessarily obtaining ideal results. For example, “optimal” placement of a subnet means selecting a more optimal subnet over another option, rather than necessarily achieving an optimal result. Similarly, “maximize” means moving towards a maximal state (e.g., up to some processing capacity limit), not necessarily achieving such a state.

Further, it is to be understood that the present disclosure will be described in terms of a given illustrative architecture; however, other architectures, structures, substrate materials and process features, and steps can be varied within the scope of the present disclosure.

It will also be understood that when an element such as a layer, region or substrate is referred to as being “on” or “over” another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

Acoustic metasurfaces are not wideband and thus generally cannot be used to mitigate a large chuck of noise spectrum. However, the constant buzzing/humming noise from servers are narrowband frequencies, as can be measured and shown experimentally. For noise suppression of servers, there is thus only a need to suppress narrowband peaks starting from the most dominant peak to generally at least two or three subsequent peaks to achieve beneficial noise suppression. On a dB scale, a 10-30 dB suppression of such peaks is possible using acoustic metasurfaces. One solution successfully employs Helmholtz resonator-based acoustic metasurfaces, which offer superior performance, but such resonators typically are relatively thick (2-4 inches in thickness, depending on the frequency or frequencies to cancel) and can use at least one unit (1U) of spacing to achieve sufficient noise suppression. Such space is valuable, and thus Helmholtz resonator-based acoustic metasurfaces are not suitable for certain server deployment scenarios.

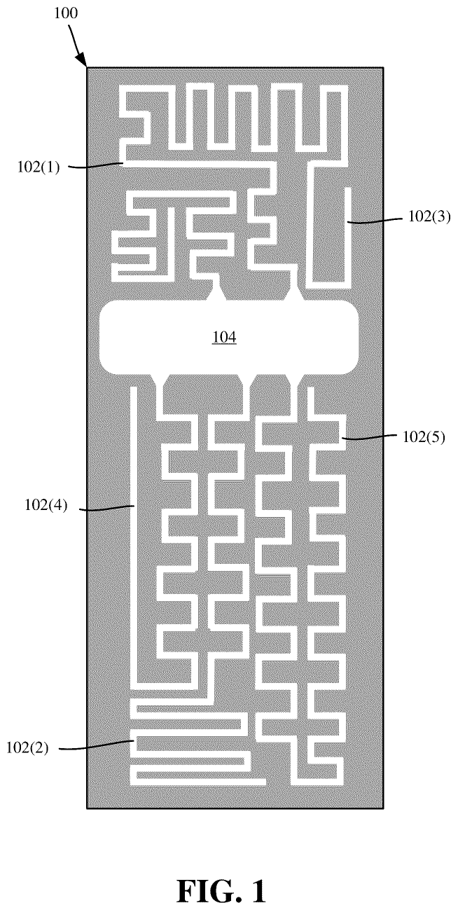

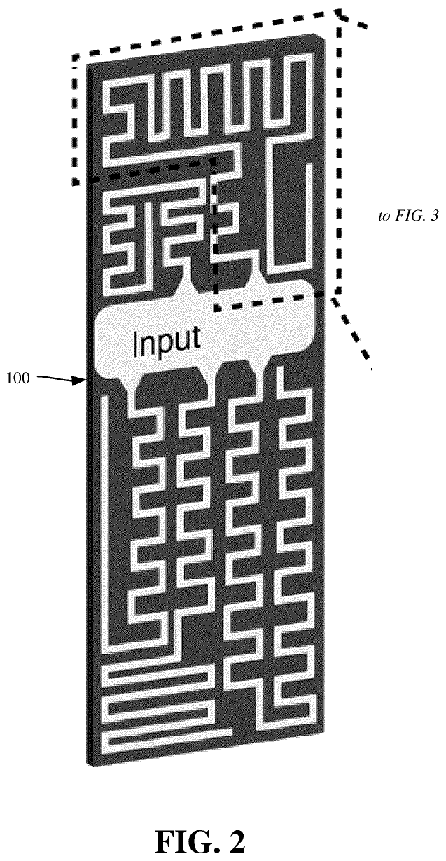

Described herein are relatively thin multiband quarter wavelength-based noise suppression modules. FIG. 1 is a top view of such a metasurface 100 that includes five distinct air trace lines 102(1)-102(5) corresponding to five passive acoustic noise suppressing resonators using quarter-wavelength cavities. The five air trace lines 102(1)-102(5) are of lengths corresponding to quarter wavelengths of five frequencies to cancel. In one implementation, the five air trace lines 102(1)-102(5) share the same intake 104. FIG. 2 is a 3D view of generally the same (or a similar) five quarter-wavelength cavities metasurface 100.

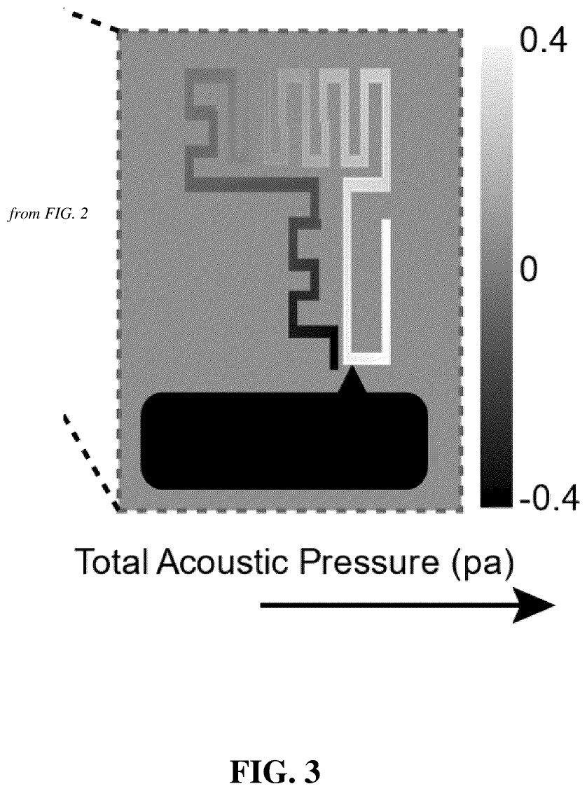

FIG. 3 is a top view showing an enlarged portion of the metasurface of FIG. 2, e.g., corresponding to the quarter-wavelength cavity/air trace line 102(3), and the acoustic pressure therein. As can be seen, the acoustic pressure (in Pascals (pa) in FIG. 3) varies in a gradient-like fashion through the air trace line.

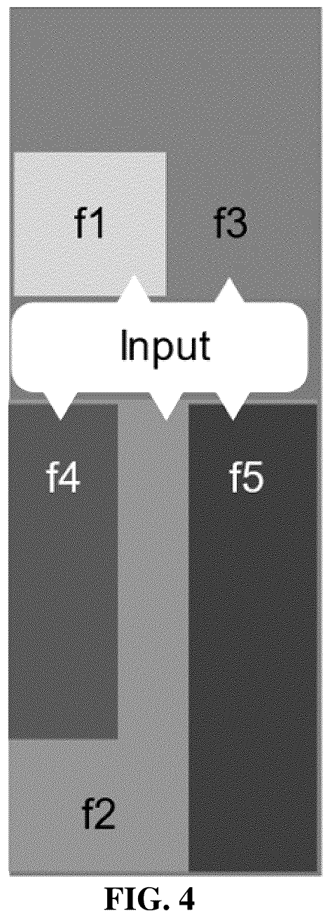

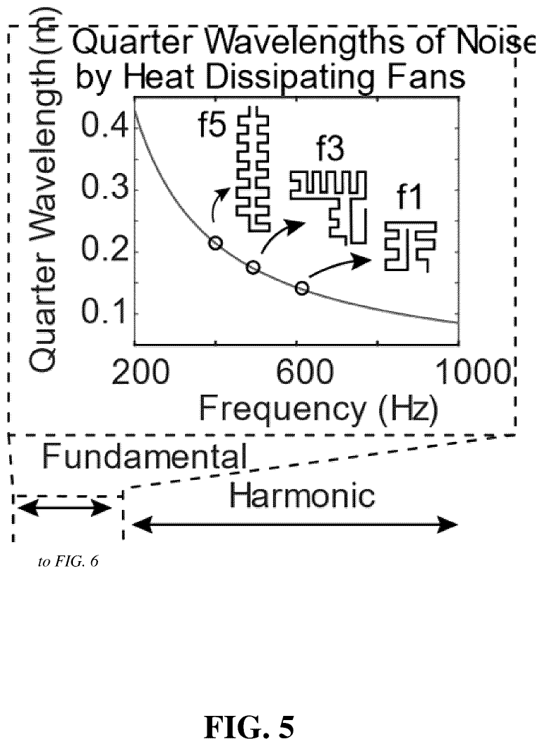

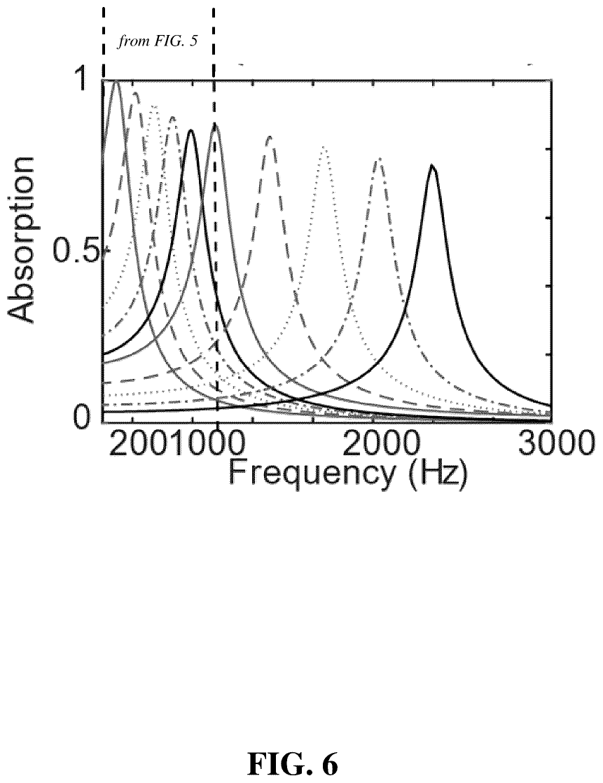

As shown in the map of FIG. 4, one noise suppression module includes five individual quarter wavelength resonators designed to suppress five fundamental tones, f1, f2, . . . f5 and their harmonics, as shown in FIGS. 5 and 6. A distinctive feature of employing a quarter-wavelength line lies in its compact design using open ended stubs. Note that such a design does not share the same design principle of other types of modules, hence the conventional tradeoff between thermal performance and sound performance can be a significant consideration. The use of a quarter wavelength resonator-type surface may be applicable to scenarios in which compactness is a significant concern, noting that some thermal performance can be sacrificed for such an objective.

Each resonator, designed for a specific noise tone, operates by dissipating the acoustic pressure into thermal heat. As such, the interior of the resonators can be plated with thermally conductive material, such as alumina nitride or any similar high thermal conductivity material, to help convey the heat away from the metasurface. For example, the module can be manufactured using copper or aluminum, and a thermally conductive coating can be applied to further dissipate the heat.

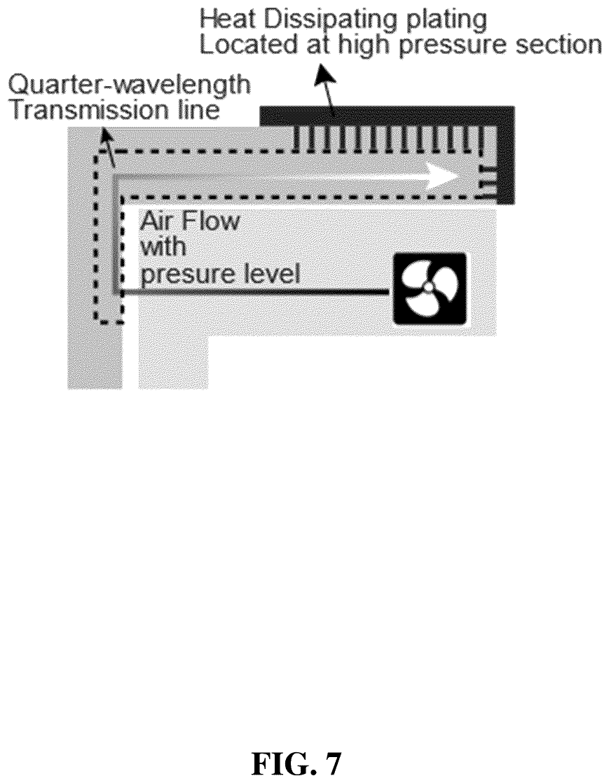

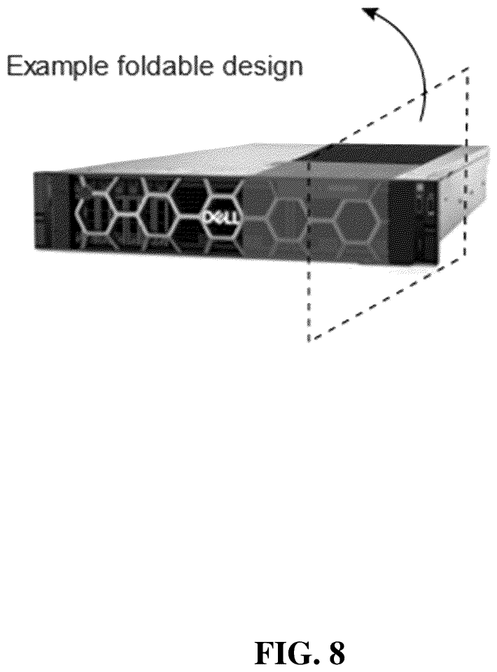

Moreover, heat dissipating plating, as generally shown in FIGS. 7 and 8, can be placed proximate to high pressure section(s) of the metasurface module. If the metasurface module is made using additive manufacturing techniques, e.g., 3D printing, a passive heatsink can be attached with thermally conductive paste. Still further, a low RPM fan such as with noise below 25 dBA, e.g., a thin profile fan, can also be used to help cool the module and the accompanying heat dissipating plating/heatsink, and thus keep the module cool.

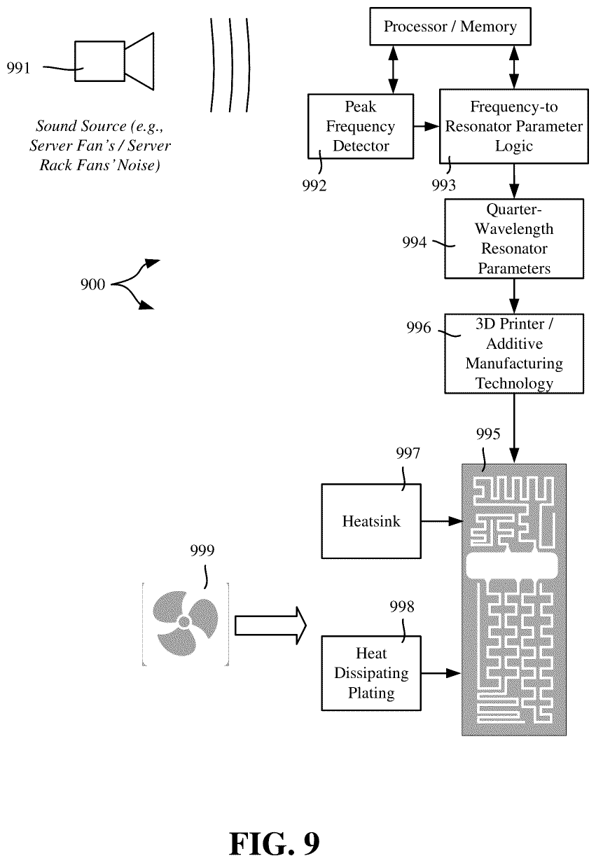

FIG. 9 shows a generalized block diagram of an example metasurface design system 900 including a sound source 991 such as server fan/fans that generate undesirable noise including at a frequency (or multiple frequencies) that are to be absorbed based on the technology described herein. The design can effectively suppress a noise frequency or frequencies; multiple frequency cancellation can be based on using different quarter-wavelength resonators that resonate at different frequencies to provide multiband/wideband noise suppression.

A frequency measurement tool can be used as a peak frequency detector 991 or the like to determine which approximate narrowband frequency (or multiple frequencies or wide band of frequencies) to cancel as described herein. For purposes of explanation herein, suppression of five fundamental frequencies and their harmonics has been described herein. As will be seen, the frequencies are absorbed efficiently by the technology described herein. In addition to the absorbed frequency, a narrow band of nearby frequencies also may be reduced to a lesser, but still desirable, extent.

Once the frequency or frequencies to cancel are determined, frequency-to-resonator parameter logic 993 (e.g., running in a processor/memory) can be used to determine the parameters 994 of the quarter-wavelength resonators that can suppress those frequencies. These structural parts of the metasurface 995 can be constructed with 3D printer/additive manufacturing technology 996, that is, printing the metasurface supporting structure in conjunction with omitting printing of the air trace lines and the intake, other than any thermally conductive coating, which are thus air cavities or coated air cavities.

Also shown in FIG. 9 are a heatsink 997, heat dissipating plating 998 and a fan 999. Any or all of these heat removal devices/concepts can be used to assist in cooling the metasurface 994.

There is thus described a quarter-wavelength-based acoustic pressure suppression resonator, which can be used in a quarter-wavelength based multi-band noise reduction module. In one implementation, an ultra-thin noise suppression module to suppress five fundamental tones and their third, fifth and higher order harmonics is presented as an example.

The quarter-wavelength-based resonators can use meandered air trace lines with impedance matching tapered input facilitating a compact design approach for noise absorption at fundamental frequencies and their harmonics. An input opening can be shared by the multiple resonators for air intake.

The interior of the resonators can be plated with thermally conductive material such as alumina nitride or any similar high thermal conductivity material. Additional thermal conductive heat dissipating plating can be added to the structure to offset its thermal performance; any high thermally conductive material can be used for the plating, such as alumina nitride (AlN). The plating can be located at high pressure section(s) of the module, and a low rpm, large size fan can be additionally used; (such fans are commercially available from various vendors). A heatsink can be strategically placed to assist in heat dissipation; e.g., a passive heatsink can be attached near high pressure area with thermal paste between the interface of additive manufacturing material and the heatsink.

One or more implementations and embodiments can be included in a device, such as described and represented in the drawing figures herein. The device can include an acoustic metasurface comprising an air intake coupled to a quarter-wavelength-based acoustic pressure suppression resonator, for noise suppression of a fundamental frequency corresponding to a quarter wavelength of the fundamental frequency. The acoustic metasurface can be configured for deployment of the acoustic metasurface proximate to a server housing of a server. When the acoustic metasurface is deployed proximate to a server, the acoustic metasurface suppresses at least some noise generated by at least one fan of the server at the fundamental frequency corresponding to the quarter wavelength.

The quarter-wavelength-based acoustic pressure suppression resonator can include a meandering air trace line.

The meandering air trace line can be coupled to sound hard material of the quarter-wavelength-based acoustic pressure suppression resonator.

At least part of an interior portion of the quarter-wavelength-based acoustic pressure suppression resonator can include high thermal conductivity material.

At least part of an exterior portion of the quarter-wavelength-based acoustic pressure suppression resonator can be coupled to heat dissipating plating.

The fundamental frequency can be a first fundamental frequency, the quarter-wavelength-based acoustic pressure suppression resonator can be a first quarter-wavelength-based acoustic pressure suppression resonator for first noise suppression of the first fundamental frequency corresponding to a first quarter wavelength of the first fundamental frequency, and the acoustic metasurface further can include a second quarter-wavelength-based acoustic pressure suppression resonator for second noise suppression of a second fundamental frequency corresponding to a second quarter wavelength of the second fundamental frequency. When the acoustic metasurface is coupled proximate to the server housing via the coupling, the acoustic metasurface can suppress at least some noise generated by the at least one fan of the server at the second fundamental frequency corresponding to the second quarter wavelength.

The first quarter-wavelength-based acoustic pressure suppression resonator and the second quarter-wavelength-based acoustic pressure suppression resonator can share the air intake.

The acoustic metasurface further can include a third quarter-wavelength-based acoustic pressure suppression resonator for third noise suppression of a third fundamental frequency corresponding to a third quarter wavelength of the third fundamental frequency. When the acoustic metasurface is coupled proximate to the server housing via the coupling, the acoustic metasurface can suppress at least some noise generated by at least one fan of the server at the third fundamental frequency corresponding to the third quarter wavelength.

The first quarter-wavelength-based acoustic pressure suppression resonator can include a first meandering air trace line, the second quarter-wavelength-based acoustic pressure suppression resonator can include a second meandering air trace line, and the third quarter-wavelength-based acoustic pressure suppression resonator can include a third meandering air trace line.

The first quarter-wavelength-based acoustic pressure suppression resonator, the second quarter-wavelength-based acoustic pressure suppression resonator, and the third quarter-wavelength-based acoustic pressure suppression resonator can share the air intake.

The acoustic metasurface further can include a fourth quarter-wavelength-based acoustic pressure suppression resonator for fourth noise suppression of a fourth fundamental frequency corresponding to a fourth quarter wavelength of the fourth fundamental frequency. When the acoustic metasurface is coupled proximate to the server housing via the coupling, the acoustic metasurface can suppress at least some noise generated by at least one fan of the server at the fourth fundamental frequency corresponding to the fourth quarter wavelength.

The acoustic metasurface further can include a fifth quarter-wavelength-based acoustic pressure suppression resonator for fifth noise suppression of a fifth fundamental frequency corresponding to a fifth quarter wavelength of the fifth fundamental frequency. When the acoustic metasurface is coupled proximate to the server housing via the coupling, the acoustic metasurface can suppress at least some noise generated by at least one fan of the server at the fifth fundamental frequency corresponding to the fifth quarter wavelength.

The first quarter-wavelength-based acoustic pressure suppression resonator can include a first meandering air trace line, the second quarter-wavelength-based acoustic pressure suppression resonator can include a second meandering air trace line, the third quarter-wavelength-based acoustic pressure suppression resonator can include a third meandering air trace line, the fourth quarter-wavelength-based acoustic pressure suppression resonator can include a fourth meandering air trace line, and the fifth quarter-wavelength-based acoustic pressure suppression resonator can include a fifth meandering air trace line.

The first quarter-wavelength-based acoustic pressure suppression resonator, the second quarter-wavelength-based acoustic pressure suppression resonator, the third quarter-wavelength-based acoustic pressure suppression resonator, the fourth quarter-wavelength-based acoustic pressure suppression resonator, and the fifth quarter-wavelength-based acoustic pressure suppression resonator can share the air intake.

One or more implementations and embodiments can be included in a system, such as described and represented in the drawing figures herein. The system can include an acoustic metasurface module comprising sound hard material. The acoustic metasurface module can include an air intake port configured for inputting acoustic waves corresponding to server noise. The acoustic metasurface module further can include respective separate meandering air trace lines coupled to the air intake port; the respective separate meandering air trace lines can include respective different lengths based on respective different quarter wavelengths of respective different fundamental frequencies of acoustic waves corresponding to the server noise suppressed by the acoustic metasurface module.

The system further can include thermally conductive material coupled to the respective separate meandering air trace lines.

The system further can include heat dissipating plating coupled to the acoustic metasurface module proximate to a first section of the acoustic metasurface module that corresponds to higher acoustic pressure relative to a second section of the acoustic metasurface module that corresponds to lower acoustic pressure.

The system further can include a fan configured to dissipate heat from the acoustic metasurface module.

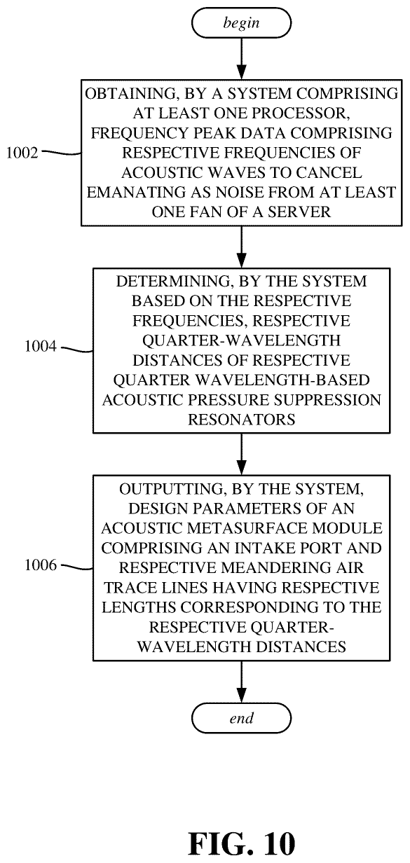

One or more example embodiments, such as corresponding to example operations of a method, system and/or machine readable medium of executable instructions is represented in FIG. 10. Example operation 1002 represents obtaining, by a system comprising at least one processor, frequency peak data comprising respective frequencies of acoustic waves to cancel emanating as noise from at least one fan of a server. Example operation 1004 represents determining, by the system based on the respective frequencies, respective quarter-wavelength distances of respective quarter wavelength-based acoustic pressure suppression resonators. Example operation 1006 represents outputting, by the system, design parameters of an acoustic metasurface module comprising an intake port and respective meandering air trace lines having respective lengths corresponding to the respective quarter-wavelength distances.

Further operations can include controlling, by the system based on the design parameters, a printer to print the acoustic metasurface module.

As can be seen, the technology described herein facilitates construction and deployment of modular metasurface designs of quarter-wavelength resonators that can be deployed for suppressing server noise. In contrast to the other metamaterials, which generally have a minimum thickness on the order of one-to-four inches depending on the frequency or frequencies to suppress, the design for a specific noise frequency target described herein achieves a reduced thickness on the order of a half-inch. This reduction is achieved by laying the line along a surface perpendicular to its depth, as opposed to its depth. The surface exhibits significant flexibility in terms of its shape, orientation, and foldability.

The above description of illustrated embodiments of the subject disclosure, comprising what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

As used in this application, the terms “component,” “system,” “platform,” “layer,” “selector,” “interface,” and the like are intended to refer to a computer-related resource or an entity related to an operational apparatus with one or more specific functionalities, wherein the entity can be either hardware, a combination of hardware and software, software, or software in execution. As an example, a component can be an apparatus with specific functionality provided by mechanical parts operated by electric or electronic circuitry. As yet another example, a component can be an apparatus that provides specific functionality through electronic components without mechanical parts, the electronic components can comprise a processor therein to execute software or firmware that confers at least in part the functionality of the electronic components.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances.

While the embodiments are susceptible to various modifications and alternative constructions, certain illustrated implementations thereof are shown in the drawings and have been described above in detail. It should be understood, however, that there is no intention to limit the various embodiments to the specific forms disclosed, but on the contrary, the intention is to cover all modifications, alternative constructions, and equivalents falling within the spirit and scope.

In addition to the various implementations described herein, it is to be understood that other similar implementations can be used or modifications and additions can be made to the described implementation(s) for performing the same or equivalent function of the corresponding implementation(s) without deviating therefrom. Still further, multiple processing chips or multiple devices can share the performance of one or more functions described herein, and similarly, storage can be effected across a plurality of devices. Accordingly, the various embodiments are not to be limited to any single implementation, but rather are to be construed in breadth, spirit and scope in accordance with the appended claims.

What is claimed is:

1. A device, comprising:
an acoustic metasurface comprising an air intake coupled to a quarter-wavelength-based acoustic pressure suppression resonator, for noise suppression of a fundamental frequency corresponding to a quarter wavelength of the fundamental frequency,
wherein the acoustic metasurface is configured for deployment of the acoustic metasurface proximate to a server housing of a server, and
wherein, when the acoustic metasurface is deployed proximate to a server, the acoustic metasurface suppresses at least some noise generated by at least one fan of the server at the fundamental frequency corresponding to the quarter wavelength.

2. The device of claim 1, wherein the quarter-wavelength-based acoustic pressure suppression resonator comprises a meandering air trace line.

3. The device of claim 1, wherein the meandering air trace line is coupled to sound hard material of the quarter-wavelength-based acoustic pressure suppression resonator.

4. The device of claim 1, wherein at least part of an interior portion of the quarter-wavelength-based acoustic pressure suppression resonator comprises high thermal conductivity material.

5. The device of claim 1, wherein at least part of an exterior portion of the quarter-wavelength-based acoustic pressure suppression resonator is coupled to heat dissipating plating.

6. The device of claim 1, wherein the fundamental frequency is a first fundamental frequency, wherein the quarter-wavelength-based acoustic pressure suppression resonator is a first quarter-wavelength-based acoustic pressure suppression resonator for first noise suppression of the first fundamental frequency corresponding to a first quarter wavelength of the first fundamental frequency, wherein the acoustic metasurface further comprises a second quarter-wavelength-based acoustic pressure suppression resonator for second noise suppression of a second fundamental frequency corresponding to a second quarter wavelength of the second fundamental frequency, and
wherein, when the acoustic metasurface is coupled proximate to the server housing via the coupling, the acoustic metasurface suppresses at least some noise generated by the at least one fan of the server at the second fundamental frequency corresponding to the second quarter wavelength.

7. The device of claim 6, wherein the first quarter-wavelength-based acoustic pressure suppression resonator and the second quarter-wavelength-based acoustic pressure suppression resonator share the air intake.

8. The device of claim 6, wherein the acoustic metasurface further comprises a third quarter-wavelength-based acoustic pressure suppression resonator for third noise suppression of a third fundamental frequency corresponding to a third quarter wavelength of the third fundamental frequency, and wherein, when the acoustic metasurface is coupled proximate to the server housing via the coupling, the acoustic metasurface suppresses at least some noise generated by at least one fan of the server at the third fundamental frequency corresponding to the third quarter wavelength.

9. The device of claim 8, wherein the first quarter-wavelength-based acoustic pressure suppression resonator comprises a first meandering air trace line, wherein the second quarter-wavelength-based acoustic pressure suppression resonator comprises a second meandering air trace line, and wherein the third quarter-wavelength-based acoustic pressure suppression resonator comprises a third meandering air trace line.

10. The device of claim 8, wherein the first quarter-wavelength-based acoustic pressure suppression resonator, the second quarter-wavelength-based acoustic pressure suppression resonator, and the third quarter-wavelength-based acoustic pressure suppression resonator share the air intake.

11. The device of claim 8, wherein the acoustic metasurface further comprises a fourth quarter-wavelength-based acoustic pressure suppression resonator for fourth noise suppression of a fourth fundamental frequency corresponding to a fourth quarter wavelength of the fourth fundamental frequency, and wherein, when the acoustic metasurface is coupled proximate to the server housing via the coupling, the acoustic metasurface suppresses at least some noise generated by at least one fan of the server at the fourth fundamental frequency corresponding to the fourth quarter wavelength.

12. The device of claim 11, wherein the acoustic metasurface further comprises a fifth quarter-wavelength-based acoustic pressure suppression resonator for fifth noise suppression of a fifth fundamental frequency corresponding to a fifth quarter wavelength of the fifth fundamental frequency, and wherein, when the acoustic metasurface is coupled proximate to the server housing via the coupling, the acoustic metasurface suppresses at least some noise generated by at least one fan of the server at the fifth fundamental frequency corresponding to the fifth quarter wavelength.

13. The device of claim 12, wherein the first quarter-wavelength-based acoustic pressure suppression resonator comprises a first meandering air trace line, wherein the second quarter-wavelength-based acoustic pressure suppression resonator comprises a second meandering air trace line, wherein the third quarter-wavelength-based acoustic pressure suppression resonator comprises a third meandering air trace line, wherein the fourth quarter-wavelength-based acoustic pressure suppression resonator comprises a fourth meandering air trace line, and wherein the fifth quarter-wavelength-based acoustic pressure suppression resonator comprises a fifth meandering air trace line.

14. The device of claim 12, wherein the first quarter-wavelength-based acoustic pressure suppression resonator, the second quarter-wavelength-based acoustic pressure suppression resonator, the third quarter-wavelength-based acoustic pressure suppression resonator, the fourth quarter-wavelength-based acoustic pressure suppression resonator, and the fifth quarter-wavelength-based acoustic pressure suppression resonator share the air intake.

15. A system comprising:
an acoustic metasurface module comprising sound hard material, the acoustic metasurface module comprising:
an air intake port configured for inputting acoustic waves corresponding to server noise; and
respective separate meandering air trace lines coupled to the air intake port, the respective separate meandering air trace lines comprising respective different lengths based on respective different quarter wavelengths of respective different fundamental frequencies of acoustic waves corresponding to the server noise suppressed by the acoustic metasurface module.

16. The system of claim 15, further comprising thermally conductive material coupled to the respective separate meandering air trace lines.

17. The system of claim 15, further comprising heat dissipating plating coupled to the acoustic metasurface module proximate to a first section of the acoustic metasurface module that corresponds to higher acoustic pressure relative to a second section of the acoustic metasurface module that corresponds to lower acoustic pressure.

18. The system of claim 15, further comprising a fan configured to dissipate heat from the acoustic metasurface module.

19. A method, comprising:
obtaining, by a system comprising at least one processor, frequency peak data comprising respective frequencies of acoustic waves to cancel emanating as noise from at least one fan of a server;
determining, by the system based on the respective frequencies, respective quarter-wavelength distances of respective quarter wavelength-based acoustic pressure suppression resonators; and
outputting, by the system, design parameters of an acoustic metasurface module comprising an intake port and respective meandering air trace lines having respective lengths corresponding to the respective quarter-wavelength distances.

20. The method of claim 19, further comprising controlling, by the system based on the design parameters, a printer to print the acoustic metasurface module.
